(19) United States
(12) Patent Application Publication
(10) Pub. No.: US 2024/0389228 A1
(43) Pub. Date: Nov. 21, 2024

(54) ELECTRONIC CONTROL DEVICE

(71) Applicant: HITACHI ASTEMO, LTD., Hitachinaka-shi, Ibaraki (JP)

(72) Inventors: Akira ISHII, Hitachinaka-shi (JP); Tomio SAKASHITA, Hitachinaka-shi (JP)

(73) Assignee: HITACHI ASTEMO, LTD., Hitachinaka-shi, Ibaraki (JP)

(21) Appl. No.: 18/691,436

(22) PCT Filed: Nov. 30, 2022
(86) PCT No.: PCT/JP2022/044080

§ 371 Date: Mar. 12, 2024

(30) Foreign Application Priority Data
Dec. 27, 2021 (JP) 2021-211811

(51) Int. Cl. H05K 1/11; H05K 1/18

(52) U.S. Cl. CPC H05K 1/113; H05K 1/181; H05K 2201/10015; H05K 2201/10545

(57) ABSTRACT

An electronic control device includes: a circuit board including first and second surfaces structured to be loaded with electronic components; a first capacitor mounted to the first surface of the circuit board; and a second capacitor mounted to the second surface of the circuit board and disposed oppositely to the first capacitor at least partially. The circuit board further includes: a first land disposed in the first surface of the circuit board and connected to the first capacitor; a second land disposed in the second surface of the circuit board and connected to the second capacitor; and a conduction passage establishing electrical continuity from the first land and the second land to a same power source line via the circuit board.

### TECHNICAL FIELD

The present invention relates to an electronic control device.

### BACKGROUND ART

Patent Document 1 exemplarily discloses a circuit board including a first-surface capacitor-mounting region and a second-surface capacitor-mounting region that are respectively formed in a first surface and a second surface of the circuit board and overlap with each other in planar view. Each of the first-surface capacitor-mounting region and the second-surface capacitor-mounting region contains capacitors disposed densely.

According to Patent Document 1, the both surfaces of the circuit board include lands for surface-mounting of the capacitors. This increases the circuit board in modulus of section, and thereby improves the circuit board in flexural rigidity.

However, Patent Document 1 fails to consider wiring lengths from the capacitors to a power module on the circuit board. Specifically, Patent Document 1 has an imbalance between wiring lengths from the capacitors on the first surface of the circuit board to the power module and wiring lengths from the capacitors on the second surface of the circuit board to the power module. This may cause unevenness in product life between the capacitors on the first surface of the circuit board and the capacitors on the second surface of the circuit board.

### PRIOR ART DOCUMENT(S)

### Patent Document(s)

Patent Document 1: JP 2020-45894 A

### SUMMARY OF THE INVENTION

According to one aspect of the present invention, an electronic control device includes: a circuit board including first and second surfaces structured to be loaded with electronic components; a first capacitor mounted to the first surface of the circuit board; and a second capacitor mounted to the second surface of the circuit board and disposed oppositely to the first capacitor at least partially. The circuit board further includes: a first land disposed in the first surface of the circuit board and connected to the first capacitor; a second land disposed in the second surface of the circuit board and connected to the second capacitor; and a conduction passage establishing electrical continuity from the first land and the second land to a same power source line via the circuit board.

The above aspect of the present invention serves to shorten a wiring length between the first capacitor and the second capacitor, and thereby reduce unevenness in product life between the first capacitor and the second capacitor.

### BRIEF DESCRIPTION OF THE DRAWINGS

FIG. 1 is an oblique view of an electric actuator device to which the present invention is applied.

FIG. 2 is a longitudinal sectional view of the electric actuator device to which the present invention is applied.

FIG. 3 is a sectional view along a line A-A shown in FIG. 2.

FIG. 4 is a sectional view along a line B-B shown in FIG. 2.

FIG. 5 is an illustrative view schematically showing a focused part of the electric actuator device according to a first embodiment.

FIG. 6 is an illustrative view schematically showing a circuit board according to a comparative example.

FIG. 7 is a circuit diagram on the circuit board according to the comparative example.

FIG. 8 is an illustrative view schematically showing a focused part of an electric actuator device according to a second embodiment.

FIG. 9 is an illustrative view schematically showing a focused part of an electric actuator device according to a third embodiment.

FIG. 10 is an illustrative view schematically showing a focused part of an electric actuator device according to a fourth embodiment.

FIG. 11 is an illustrative view schematically showing a focused part of an electric actuator device according to a fifth embodiment.

FIG. 12 is an illustrative view schematically showing a focused part of an electric actuator device according to a sixth embodiment.

FIG. 13 is an illustrative view schematically showing a focused part of an electric actuator device according to a seventh embodiment.

FIG. 14 is an illustrative view schematically showing a focused part of the electric actuator device according to the seventh embodiment.

FIG. 15 is an illustrative view schematically showing a focused part of an electric actuator device according to another embodiment.

FIG. 16 is an illustrative view schematically showing a focused part of an electric actuator device according to an eighth embodiment.

FIG. 17 is an illustrative view schematically showing a focused part of an electric actuator device according to a ninth embodiment.

FIG. 18 is an illustrative view schematically showing a focused part of an electric actuator device according to a tenth embodiment.

FIG. 19 is an illustrative view schematically showing a focused part of an electric actuator device according to an eleventh embodiment.

FIG. 20 is an illustrative view schematically showing a focused part of an electric actuator device according to a twelfth embodiment.

FIG. 21 is an illustrative view schematically showing a focused part of an electric actuator device according to a thirteenth embodiment.

FIG. 22 is an illustrative view schematically showing a focused part of an electric actuator device according to a fourteenth embodiment.

FIG. 23 is an illustrative view schematically showing a focused part of an electric actuator device according to a fifteenth embodiment.

FIG. 24 is an illustrative view schematically showing a focused part of an electric actuator device according to a sixteenth embodiment.

### MODE(S) FOR CARRYING OUT THE INVENTION

The following details a first embodiment of the present invention with reference to the drawings.

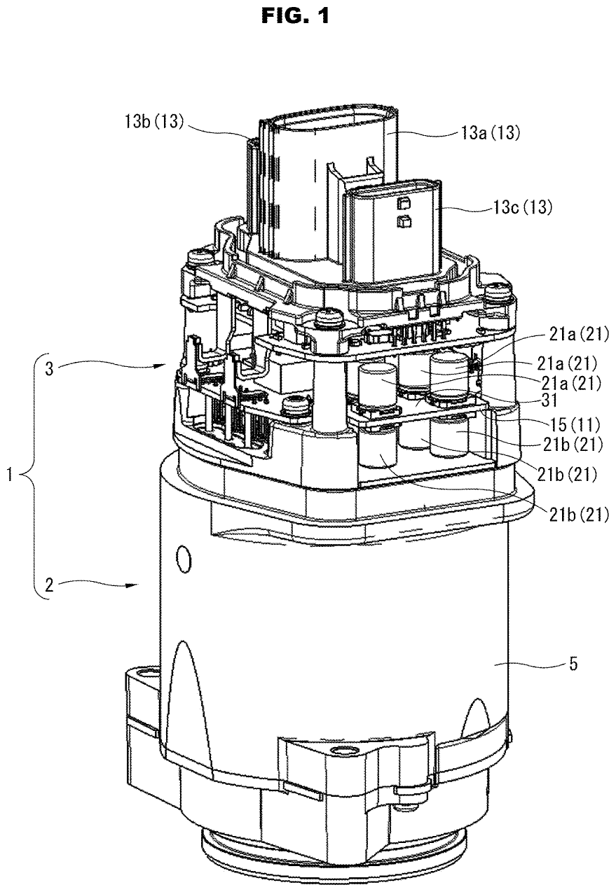

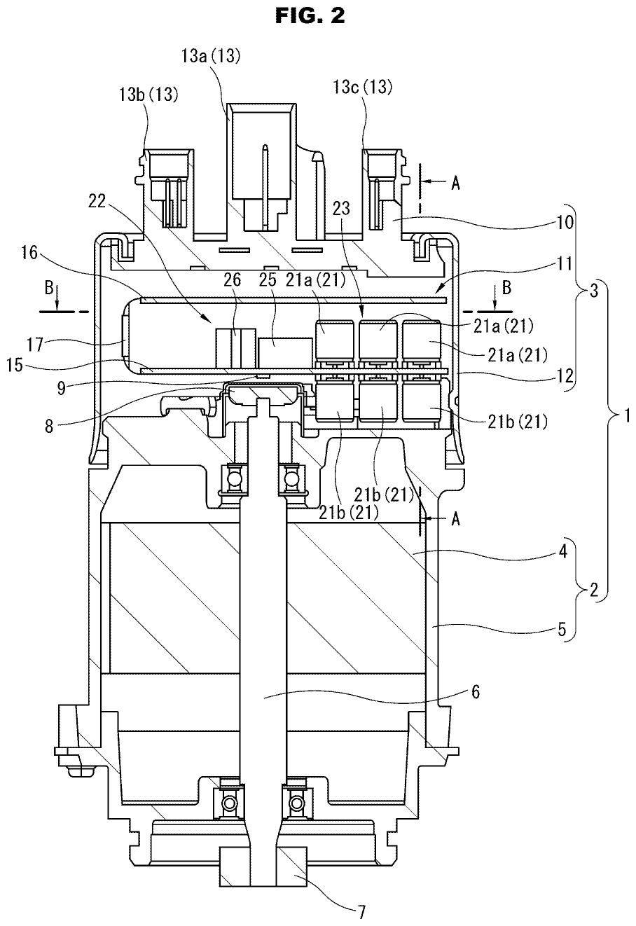

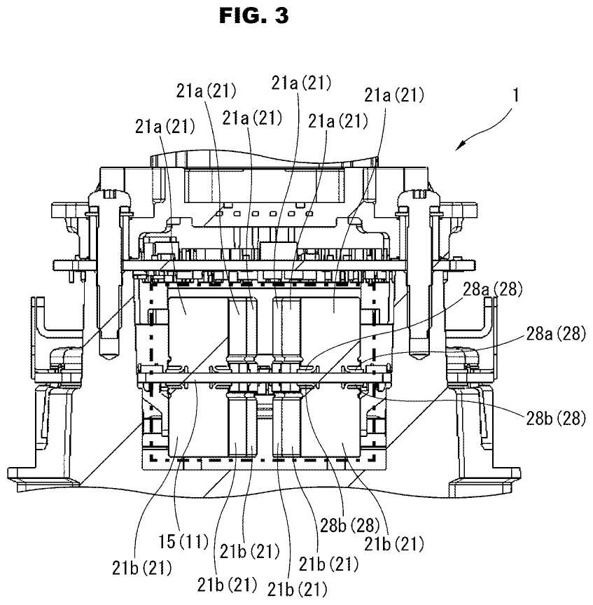

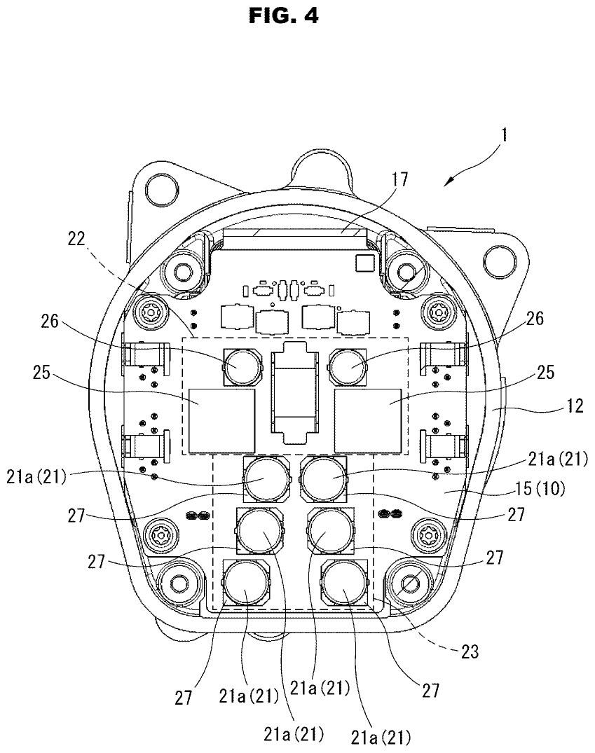

FIG. 1 is an oblique view of an electric actuator device 1 to which the present invention is applied. FIG. 2 is a longitudinal sectional view of electric actuator device 1 to which the present invention is applied. FIG. 3 is a sectional view along a line A-A shown in FIG. 2. FIG. 4 is a sectional view along a line B-B shown in FIG. 2. Electric actuator device 1 corresponds to an electronic control device, and is structured to provide steering assist force for a steering mechanism, in an electric power steering device for an automobile.

As shown in FIGS. 1 and 2, electric actuator device 1 includes a motor unit 2 and a controller 3. Motor unit 2 has a cylindrical shape. Controller 3 controls driving of motor unit 2.

Motor unit 2 includes a motor 4 and a housing 5. Motor 4 corresponds to an electric actuator. Housing 5 has a cylindrical shape and contains motor 4. Motor 4 is a three-phase permanent magnet type brushless motor, and includes a stator and a rotor. The stator includes coils of three phases. The rotor includes an outer peripheral surface on which permanent magnets are disposed. For redundancy, motor 4 includes two systems of the coils and the permanent magnets.

Motor 4 includes a rotational shaft 6. Rotational shaft 6 includes a first end projecting from a tip surface of housing 5 and including a tip to which a coupler 7 such as a gear or a spline is mounted, and includes a second end to which a magnet 8 is mounted. Magnet 8 is structured to rotate integrally with rotational shaft 6 and generate rotating magnet field. The rotating magnet field is measured by a sensor 9. This allows determination of a rotational angle of the rotor.

Controller 3 includes a connector unit 10, a circuit board 11, and a motor cover 12. Connector unit 10 is an integral assembly of a plurality of connectors. Circuit board 11 includes a bendable multi-layer circuit board. Motor cover 12 covers connector unit 10 and circuit board 11. In FIG. 1, motor cover 12 is omitted.

Connector unit 10 includes three connectors 13 directed in a same direction, i.e., an axial direction of rotational shaft 6. Connectors 13 are a power supply connector 13a positioned centrally, a sensor input connector 13b, and a communication connector 13c. Power supply connector 13a receives power supplied from a battery not shown serving as a power source of motor 4. Sensor input connector 13b receives signals inputted from sensors (e.g., a steering angle sensor, a torque sensor, etc.) disposed in a steering mechanism. Communication connector 13c serves for communication (e.g., CAN communication) with other control devices in a vehicle.

As shown in FIG. 2, circuit board 11 is bent from a flat shape into a substantially U shape, and is installed in electric actuator device 1. Circuit board 11 includes a first rigid part 15, a second rigid part 16, and a flexible part 17. First rigid part 15 is a power circuit board loaded with electronic components in which a relatively large electric current flows for driving of motor 4. Second rigid part 16 is a control circuit board loaded with control electronic components in which a relatively small current flows. Flexible part 17 is disposed between first rigid part 15 and second rigid part 16.

Circuit board 11 is contained in motor cover 12 in a state in which flexible part 17 is bent such that first rigid part 15 and second rigid part 16 overlap with each other in the axial direction of rotational shaft 6.

In circuit board 11 in the bent state, the electronic components mounted to first rigid part 15 and the electronic components mounted to second rigid part 16 are apart from each other by a distance sufficient to avoid contact therebetween. Furthermore, in circuit board 11 in the bent state, first rigid part 15 and second rigid part 16 are fixed to and supported by motor unit 2 while being parallel with each other and facing each other.

Circuit board 11 is formed by laminating base material layers via pre-pregs (i.e., adhesive layers) and then pressing, heating, and thereby integrating the laminated layers. Each of the base material layers is made of a base material such as a glass epoxy, and is provided with a metal foil layer(s) on one surface or both surfaces thereof.

As shown in FIGS. 1 to 4, first rigid part 15 is loaded with cylindrical electrolytic capacitors 21 on both surfaces thereof.

Electrolytic capacitors 21 form a smoothing circuit 23. Smoothing circuit 23 is structured to smooth direct-current power supplied from the battery not shown serving as the power source of motor 4, via power supply connector 13a and a filter circuit 22 (see FIGS. 2 and 4) serving as a second circuit section.

Filter circuit 22 is structured to remove noise, and corresponds to a first circuit section (i.e., a capacitor section). Filter circuit 22 serves as a so-called low-pass filter. Filter circuit 22 includes a coil 25 (e.g., a choke coil) and a capacitor 26. Coil 25 is a filter circuit component for removal of noise, and is mounted to a first mounting surface 31 of circuit board 11.

Smoothing circuit 23 is structured to supply the smoothed direct-current power to an inverter power module not shown. The inverter power module is contained in motor cover 12, and is structured to convert the smoothed direct-current power supplied from smoothing circuit 23, into an alternating-current power for driving of motor 4. The inverter power module is connected to motor 4.

Smoothing circuit 23 includes electrolytic capacitors 21 connected in parallel. Each of electrolytic capacitors 21 is mounted to circuit board 11 via a seat 27. Seats 27 are made of a material such as a resin, and serve to reduce a risk of toppling of electrolytic capacitors 21 mounted on circuit board 11. Each of electrolytic capacitors 21 includes electrode terminals 28 that extend through seat 27 and are soldered to circuit board 11.

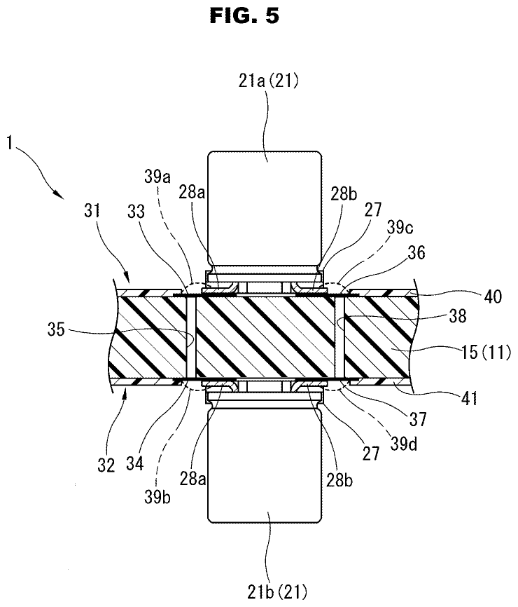

FIG. 5 is an illustrative view schematically showing a focused part of electric actuator device 1 according to the first embodiment: in detail, a focused part of first rigid part 15 loaded with electrolytic capacitors 21. Each of electrolytic capacitors 21 includes a first electrode terminal 28a of an anode side and a second electrode terminal 28b of a cathode side (i.e., a ground side).

As shown in FIG. 5, electrolytic capacitors 21 are mounted on the both surfaces of first rigid part 15 of circuit board 11, and are arranged to form upper-and-lower pairs each of which is composed of: one of first capacitors 21a (i.e., upper ones of electrolytic capacitors 21) mounted on first mounting surface 31; and a corresponding one of second capacitors 21b (i.e., lower ones of electrolytic capacitors 21) mounted on second mounting surface 32. Each of first capacitors 21a is disposed oppositely to the corresponding one of second capacitors 21b across first rigid part 15. First mounting surface 31 is one of mounting surfaces formed in the both surfaces of circuit board 11, and second mounting surface 32 is the other of the mounting surfaces. First mounting surface 31 of first rigid part 15 faces second rigid part 16. First capacitors 21a and second capacitors 21b forming the upper-and-lower pairs are same with each other in performance, i.e., same with each other in capacitance.

First rigid part 15 of circuit board 11 includes first lands 33, second lands 34, and first through holes 35. Each of first lands 33 is formed in first mounting surface 31, and is connected to a corresponding one of first electrode terminals 28a of first capacitors 21a. Each of second lands 34 is formed in second mounting surface 32, and is connected to a corresponding one of first electrode terminals 28a of second capacitors 21b. Each of first through holes 35 is a conduction passage establishing electrical continuity between a corresponding pair of first land 33 and second land 34.

In other words, first rigid part 15 of circuit board 11 includes first lands 33, second lands 34, and first through holes 35, wherein second lands 34 are connected with ones of electrode terminals 28 of second capacitors 21b same in polarity with ones of electrode terminals 28 of first capacitors 21a connected with first lands 33.

First lands 33 and second lands 34 are connected to a same power source line or a same positive wiring. This power source line is an anode power source path being a wiring with an anode potential and connecting the battery to the inverter power module, and is formed in first mounting surface 31 of first rigid part 15 of circuit board 11. Second capacitors 21b out of the capacitors 21a and 21b is electrically continuous with the power source line via first through holes 35. Thus, second capacitors 21b are connected to filter circuit 22 via first through holes 35.

Each of first through holes 35 is positioned outside first capacitor 21a and second capacitor 21b in a radial direction of first capacitor 21a and second capacitor 21b, when viewed from a direction perpendicular to the mounting surfaces 31 and 32 of circuit board 11. Each of first through holes 35 extends through first rigid part 15, and includes a first end disposed in first land 33 and a second end disposed in second land 34. According to the first embodiment, openings of the first ends and the second ends of first through holes 35 are closed with plating or resin.

First rigid part 15 of circuit board 11 includes third lands 36, fourth lands 37, and second through holes 38. Each of third lands 36 is formed in first mounting surface 31, and is connected to a corresponding one of second electrode terminals 28b of first capacitors 21a. Each of fourth lands 37 is formed in second mounting surface 32, and is connected to a corresponding one of second electrode terminals 28b of second capacitors 21b. Each of second through holes 38 is a conduction passage establishing electrical continuity between a corresponding pair of third land 36 and fourth land 37.

In other words, first rigid part 15 of circuit board 11 includes third lands 36, fourth lands 37, and second through holes 38, wherein fourth lands 37 are connected with ones of electrode terminals 28 of second capacitors 21b same in polarity with ones of electrode terminals 28 of first capacitors 21a connected with third lands 36.

Third lands 36 and fourth lands 37 are connected to a same wiring line (e.g., a ground line) with a cathode potential or a same negative wiring.

Each of second through holes 38 is positioned outside first capacitor 21a and second capacitor 21b in the radial direction of first capacitor 21a and second capacitor 21b, when viewed from the direction perpendicular to the mounting surfaces 31 and 32 of circuit board 11. Each of second through holes 38 extends through first rigid part 15, and includes a first end disposed in third lands 36 and a second end disposed in fourth lands 37. According to the first embodiment, openings of the first ends and the second ends of second through holes 38 are closed with plating or resin.

Each of first lands 33 and third lands 36 is formed to partially overlap with an undersurface of a body of first capacitor 21a.

Each of second lands 34 and fourth lands 37 is formed to partially overlap with an undersurface of a body of second capacitor 21b.

Each of first through holes 35 and second through holes 38 establishes connection between terminals with a same polarity in a pair of first capacitor 21a and second capacitor 21b.

In each of first through holes 35, the first end of first through hole 35 is positioned in an undersurface side (i.e., a side to face the circuit board) of a solder 39a disposed on first land 33, while the second end of first through hole 35 is positioned in an undersurface side (i.e., a side to face the circuit board) of a solder 39b disposed on second land 34. Solders 39a fix first electrode terminals 28a of first capacitors 21a to first lands 33. Solders 39b fix first electrode terminals 28a of second capacitors 21b to second lands 34.

In each of second through holes 38, the first end of second through hole 38 is positioned in an undersurface side (i.e., a side to face the circuit board) of a solder 39c disposed on third land 36, while the second end of second through hole 38 is positioned in an undersurface side (i.e., a side to face the circuit board) of a solder 39d disposed on fourth land 37. Solders 39c fix second electrode terminals 28b of first capacitors 21a to third lands 36. Solders 39d fix second electrode terminals 28b of second capacitors 21b to fourth lands 37.

Each of first lands 33, second lands 34, third lands 36, fourth lands 37, first through holes 35, and second through holes 38 is formed in first rigid part 15 so as to be provided for every upper-and-lower pair of electrolytic capacitors 21.

First rigid part 15 is formed such that in each of first through holes 35, a distance from first through hole 35 to first electrode terminal 28a of first capacitor 21a connected to first land 33 is smaller than a diameter of first capacitor 21a. Furthermore, first rigid part 15 is formed such that in each of first through holes 35, a distance from first through holes 35 to first electrode terminal 28a of second capacitor 21b connected to second land 34 is smaller than a diameter of second capacitors 21b.

First rigid part 15 is formed such that in each of second through holes 38, a distance from second through hole 38 to second electrode terminals 28b of first capacitor 21a connected to third land 36 is smaller than a diameter of first capacitor 21a. Furthermore, first rigid part 15 is formed such that in each of second through holes 38, a distance from second through hole 38 to second electrode terminals 28b of second capacitor 21b connected to fourth land 37 is smaller than a diameter of second capacitor 21b.

First rigid part 15 is formed such that a wiring distance between first capacitor 21a and second capacitor 21b is shorter than a diameter of electrolytic capacitor 21.

Reference numeral 40 in FIG. 5 represents a resist (i.e., a first resist) covering first lands 33 and third lands 36 on first mounting surface 31. Reference numeral 41 in FIG. 5 represents a resist (i.e., a second resist) covering second lands 34 and fourth lands 37 on second mounting surface 32.

In case of intending to increase an output of the power supplied from smoothing circuit 23 to the inverter power module, it is possible to increase a number of electrolytic capacitors 21 mounted for smoothing. However, if mounting a large number of electrolytic capacitors 21 to one surface of circuit board 11 for increasing the output, circuit board 11 may be deteriorated in flexibility of design: e.g., the other circuit(s) may be forced to move to another circuit board.

In case of intending to increase the output of the power supplied from smoothing circuit 23 to the inverter power module, it is also possible to increase electrolytic capacitors 21 for smoothing in capacitance (i.e., electric capacity). However, electrolytic capacitors 21 would increase in size with increase in capacitance.

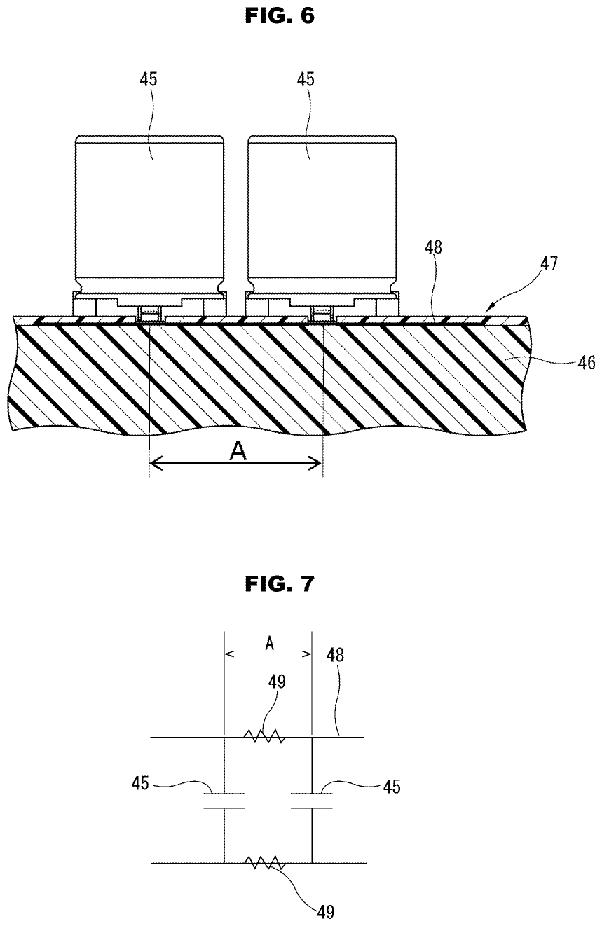

FIG. 6 is an illustrative view schematically showing a circuit board 46 according to a comparative example. FIG. 7 is a circuit diagram of circuit board 46 according to the comparative example shown in FIG. 6.

As shown in FIGS. 6 and 7, circuit board 46 includes a mounting surface 47 loaded with a pair of cylindrical electrolytic capacitors 45, 45 arranged adjacently to each other and connected in parallel with each other to a wiring pattern 48 formed in mounting surface 47. The pair of electrolytic capacitors 45, 45 have therebetween a wiring length A depending on sizes of the pair of electrolytic capacitors 45, 45. Accordingly, increase in capacitance (i.e., electric capacity) of electrolytic capacitors 45, 45 increases wiring length A in wiring pattern 48, and thereby causes problems such as increase in wiring inductance and deterioration in unevenness in product life of capacitors. Furthermore, electrolytic capacitors for smoothing increase in ripple current with increase in capacitance. Reference numeral 49 in FIG. 7 represents a wiring resistance.

On the other hand, electric actuator device 1 according to the first embodiment described above is formed such that projections (i.e., first projections) of first capacitors 21a projected in the direction perpendicular to first mounting surface 31 of circuit board 11 onto a projective plane parallel with circuit board 11 entirely overlaps with projections (i.e., second projections) of second capacitors 21b projected in the direction perpendicular to second mounting surface 32 of circuit board 11 onto the projective plane parallel with circuit board 11.

In other words, each pair of first capacitor 21a and second capacitor 21b are respectively disposed on first mounting surface 31 and second mounting surface 32 (i.e., an obverse and a reverse) of circuit board 11, and are same with each other in performance, and are arranged such that the projections of first capacitor 21a and second capacitor 21b in the direction perpendicular to circuit board 11 overlap with each other entirely.

This serves to: reduce electric actuator device 1 in wiring length between first capacitors 21a and second capacitors 21b; reduce electric actuator device 1 in wiring inductance; and reduce differences between first capacitors 21a and second capacitors 21b in wiring distance from the inverter power module, and thereby reduce unevenness in product life between first capacitors 21a and second capacitors 21b.

First capacitors 21a and second capacitors 21b are disposed entirely oppositely to each other across circuit board 11. This reduces a sum of projective areas of first capacitors 21a and second capacitors 21b in the direction perpendicular to circuit board 11 onto a projective plane parallel with circuit board 11, when viewed from the direction perpendicular to circuit board 11. This serves to improve circuit board 11 in design flexibility for mounting electronic components to circuit board 11.

In electric actuator device 1, electrolytic capacitors 21 for smoothing are disposed on the both surfaces of first rigid part 15 of circuit board 11. This allows circuit board 11 to be loaded with an increased number of electrolytic capacitors 21 for smoothing, in comparison with a case of disposing electrolytic capacitors 21 for smoothing on one surface of first rigid part 15. This serves to reduce a capacitance per capacitor of electrolytic capacitors 21 for smoothing, and reduce the ripple current flowing in smoothing circuit 23.

Electric actuator device 1 is allowed to be loaded with an increased number of electrolytic capacitors 21 for smoothing, in comparison with the case of disposing electrolytic capacitors 21 for smoothing on one surface of first rigid part 15. This serves to reduce a current value per capacitor of electric current flowing in electrolytic capacitors 21 for smoothing, and thereby reduce heat generation in electrolytic capacitors 21 for smoothing. This allows electric actuator device 1 to simplify a cooling structure for smoothing circuit 23 provided as a countermeasure against the heat generation in electrolytic capacitors 21 for smoothing, and thereby reduces electric actuator device 1 in cost.

In electric actuator device 1, second capacitors 21b are connected to filter circuit 22 via first through holes 35. This serves to shorten wiring lengths between second capacitors 21b and the filter circuit component, and reduce noise after filter processing.

In electric actuator device 1, the ground of circuit board 11, the cathodes of electrolytic capacitors 21, and wirings on circuit board 11 may be different from each other in electric potential, but can be deemed equal to each other in electric potential.

The following describes other embodiments of the present invention. The configurations same with the first embodiment above are represented by the same reference numerals, omitting repetitive explanations thereof.

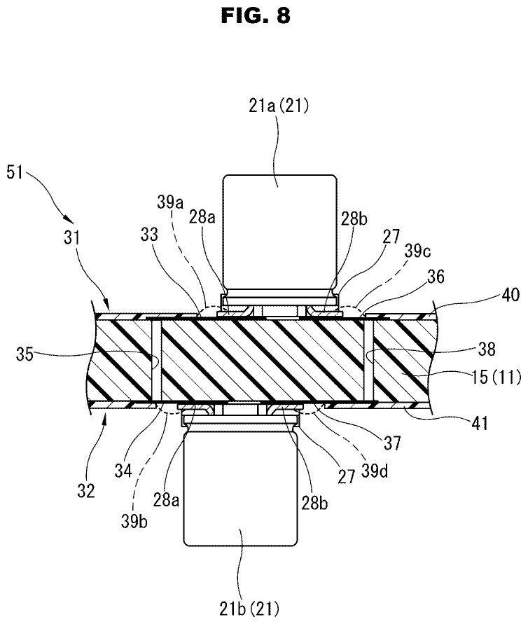

FIG. 8 is an illustrative view schematically showing a focused part of an electric actuator device 51 according to a second embodiment: in detail, a focused part of first rigid part 15 loaded with electrolytic capacitors 21.

Electric actuator device 51 according to the second embodiment is configured generally similarly to electric actuator device 1 according to the first embodiment, but is formed such that first capacitors 21a and second capacitors 21b are mounted to circuit board 11 so as to partially overlap with each other when viewed from the direction perpendicular to circuit board 11.

Thus, electric actuator device 51 according to the second embodiment is formed such that the projections (i.e., the first projections) of first capacitors 21a projected in the direction perpendicular to first mounting surface 31 of circuit board 11 onto a projective plane parallel with circuit board 11 overlaps at least partially with the projections (i.e., the second projections) of second capacitors 21b projected in the direction perpendicular to second mounting surface 32 of circuit board 11 onto the projective plane parallel with circuit board 11.

In electric actuator device 51 according to the second embodiment, each of first through holes 35 is disposed such that the first end is positioned outside first land 33, and the second end is positioned in second land 34. Each of second through holes 38 is disposed such that the first end is positioned in third land 36, and the second end is positioned outside fourth land 37.

Electric actuator device 51 according to the second embodiment presents effects substantially same with electric actuator device 1 according to the first embodiment.

However, in comparison with electric actuator device 1 according to the first embodiment, the effects presented by electric actuator device 51 according to the second embodiment decreases with decrease in amount of overlapping between the first projections of first capacitors 21a and the second projections of second capacitors 21b.

FIG. 9 is an illustrative view schematically showing a focused part of an electric actuator device 52 according to a third embodiment: in detail, a focused part of first rigid part 15 loaded with electrolytic capacitors 21.

Electric actuator device 52 according to the third embodiment is configured generally similarly to electric actuator device 1 according to the first embodiment, but is formed such that the openings of the first ends of first through holes 35 are not closed, and first through holes 35 are open in first lands 33.

In electric actuator device 52 according to the third embodiment, also the openings of the second ends of first through holes 35 are not closed although omitted in the drawing.

Actuator device 52 according to the third embodiment presents effects substantially same with electric actuator device 1 according to the first embodiment.

In addition, electric actuator device 52 according to the third embodiment may be configured such that the openings of the both ends of second through holes 38 are not closed, and second through holes 38 are open in third lands 36 and fourth lands 37.

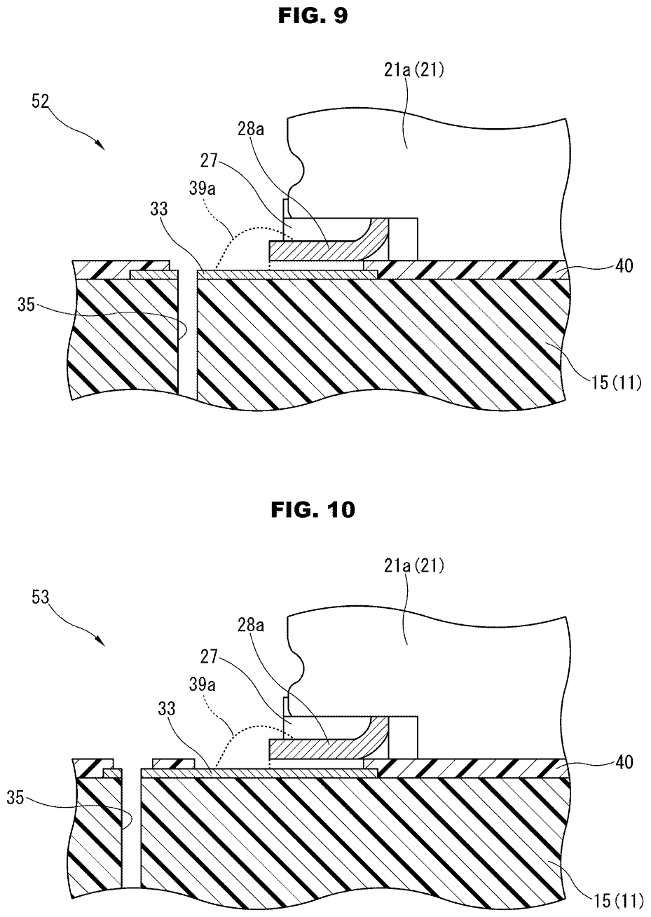

FIG. 10 is an illustrative view schematically showing a focused part of an electric actuator device 53 according to a fourth embodiment: in detail, a focused part of first rigid part 15 loaded with electrolytic capacitors 21.

Electric actuator device 53 according to the fourth embodiment is configured generally similarly to electric actuator device 1 according to the first embodiment, but is formed such that first through holes 35 are positioned outside first lands 33, and the first ends of first through holes 35 are not closed.

In detail, in electric actuator device 53 according to the fourth embodiment, each of first through holes 35 is positioned outside first capacitor 21a in the radial direction of first capacitor 21a, when viewed from the direction perpendicular to first mounting surface 31 of circuit board 11. Furthermore, although omitted in the drawing, each of first through holes 35 is positioned outside second land 34 and outside first capacitor 21b in the radial direction of first capacitor 21b, when viewed from the direction perpendicular to first mounting surface 31 of circuit board 11.

Electric actuator device 53 according to the fourth embodiment presents effects substantially same with electric actuator device 1 according to the first embodiment.

Electric actuator device 53 according to the fourth embodiment may be formed such that each of second through holes 38 is positioned outside third land 36 and fourth land 37 and outside first capacitor 21a and second capacitor 21b in the radial direction, when viewed from the direction perpendicular to first mounting surface 31 of circuit board 11. Furthermore, electric actuator device 53 according to the fourth embodiment may be formed such that the both ends of each of second through holes 38 are not closed.

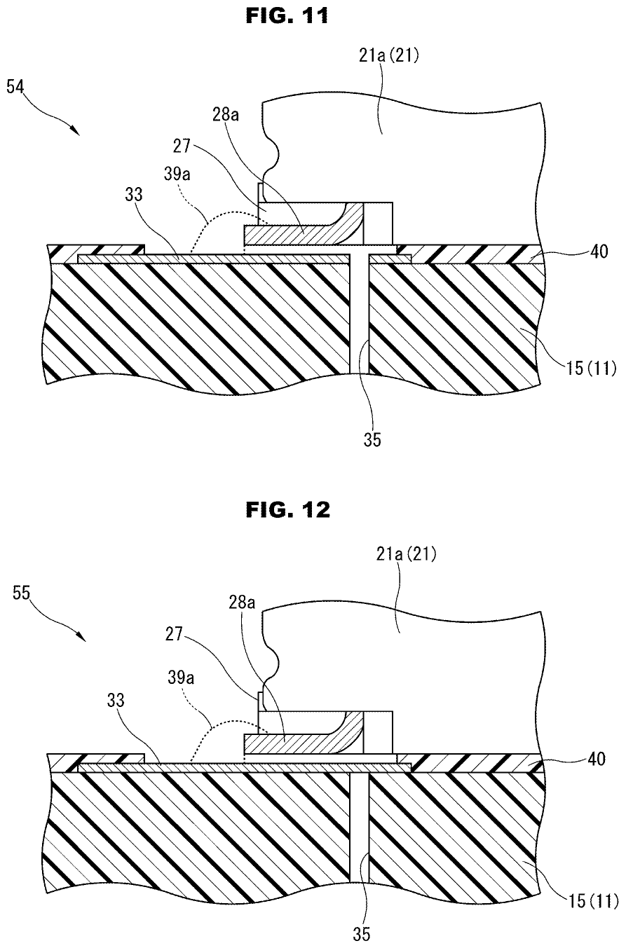

FIG. 11 is an illustrative view schematically showing a focused part of an electric actuator device 54 according to a fifth embodiment: in detail, a focused part of first rigid part 15 loaded with electrolytic capacitors 21.

Electric actuator device 54 according to the fifth embodiment is configured generally similarly to electric actuator device 1 according to the first embodiment, but is formed such that the first end of each of first through holes 35 faces a bottom surface of the body of first capacitor 21a, and the opening of the first end is not closed. Thus, in electric actuator device 54 according to the fifth embodiment, each of first through holes 35 is positioned inside first capacitor 21a in the radial direction of first capacitor 21a, i.e., positioned to overlap with first capacitor 21a, when viewed from the direction perpendicular to first mounting surface 31 of circuit board 11.

Although omitted in the drawing, in electric actuator device 54 according to the fifth embodiment, the second end of each of first through holes 35 faces a bottom surface of the body of second capacitor 21b, and the opening of the second end is not closed. Thus, in electric actuator device 54 according to the fifth embodiment, each of first through holes 35 is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11.

Electric actuator device 54 according to the fifth embodiment presents effects substantially same with electric actuator device 1 according to the first embodiment.

Electric actuator device 54 according to the fifth embodiment may be formed such that the first end of each of second through holes 38 faces the bottom surface of the body of first capacitor 21a, and the second end of each of second through holes 38 faces the bottom surface of the body of second capacitor 21b. In other words, electric actuator device 54 according to the fifth embodiment may be formed such that each of second through holes 38 is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11. Furthermore, each of second through holes 38 may be formed such that the both ends are not closed.

FIG. 12 is an illustrative view schematically showing a focused part of an electric actuator device 55 according to a sixth embodiment: in detail, a focused part of first rigid part 15 loaded with electrolytic capacitors 21.

Electric actuator device 55 according to the sixth embodiment is configured generally similarly to electric actuator device 1 according to the first embodiment, but is formed such that the first end of each of first through holes 35 faces the bottom surface of the body of first capacitor 21a. Thus, in electric actuator device 55 according to the sixth embodiment, each of first through holes 35 is positioned inside first capacitor 21a in the radial direction of first capacitor 21a, i.e., positioned to overlap with first capacitor 21a, when viewed from the direction perpendicular to first mounting surface 31 and second mounting surface 32 of circuit board 11.

Although omitted in the drawing, in electric actuator device 55 according to the sixth embodiment, the second end of each of first through holes 35 faces the bottom surface of the body of second capacitor 21b. Thus, in electric actuator device 55 according to the sixth embodiment, each of first through holes 35 is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11.

Electric actuator device 55 according to the sixth embodiment presents effects substantially same with electric actuator device 1 according to the first embodiment.

Electric actuator device 55 according to the sixth embodiment may be formed such that the first end of each of second through holes 38 faces the bottom surface of the body of first capacitor 21a, and the second end of each of second through holes 38 faces the bottom surface of the body of second capacitor 21b. In other words, electric actuator device 55 according to the sixth embodiment may be formed such that each of second through holes 38 is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11.

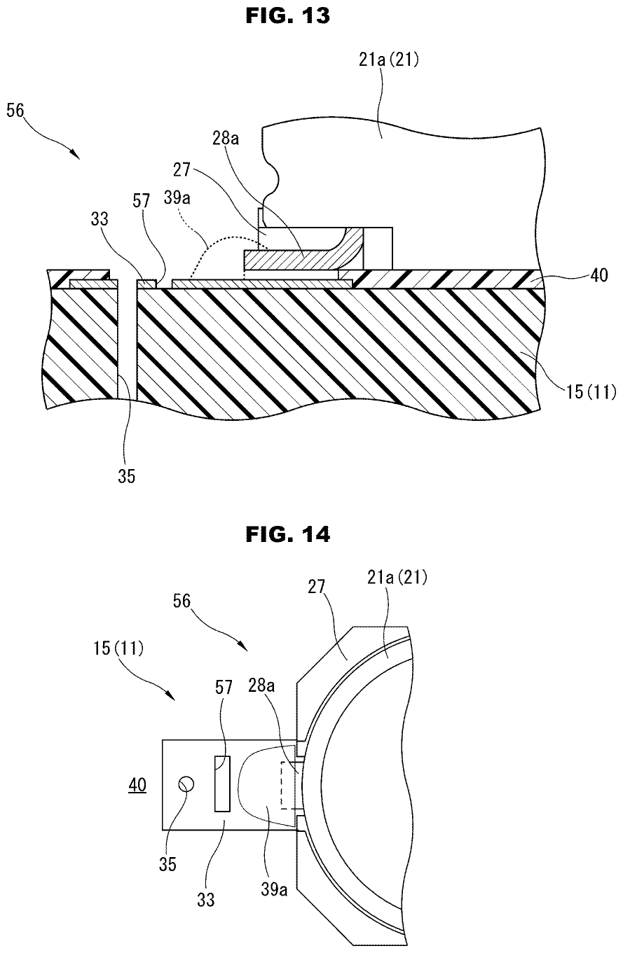

FIG. 13 is an illustrative view schematically showing a focused part of an electric actuator device 56 according to a seventh embodiment: in detail, a focused part of first rigid part 15 loaded with electrolytic capacitors 21. FIG. 14 is an illustrative view schematically showing in planar view a focused part of electric actuator device 56 according to the seventh embodiment: in detail, a focused part of first rigid part 15 loaded with electrolytic capacitors 21.

Electric actuator device 56 according to the seventh embodiment is configured generally similarly to electric actuator device 1 according to the first embodiment, but is formed such that each of first lands 33 includes an opening (i.e., a slit) 57 extending through first land 33. Each of openings 57 is a rectangular through hole extending through first land 33, and is positioned between two points in first lands 33: a capacitor connection point in first land 33 connected to first electrode terminal 28a of first capacitor 21a, and a conduction passage connection point in first land 33 connected to first through hole 35.

In detail, each of openings 57 is positioned between first through hole 35 and solder 39a fixing first electrode terminal 28a of first capacitor 21a to first land 33. Furthermore, each of openings 57 faces the capacitor connection point and the conduction passage connection point, when viewing first rigid part 15 in planar view. Each of openings 57 is positioned outside first capacitor 21a in the radial direction of first capacitor 21a.

Each of openings 57 includes an interior that does not contain copper foil forming first land 33, wherein the interior is an insulated region.

Electric actuator device 56 according to the seventh embodiment presents effects substantially same with electric actuator device 1 according to the first embodiment.

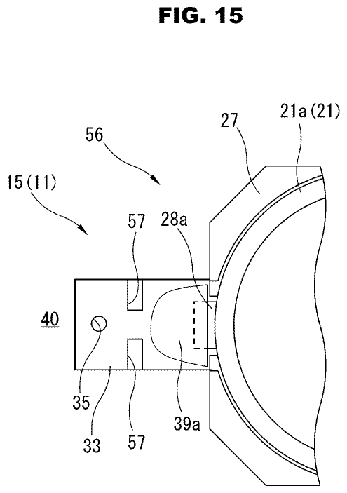

In another manner, as shown in FIG. 15, each of openings 57 may be divided into two parts so as not to overlap with a shortest path between the capacitor connection point and the conduction passage connection point.

Electric actuator device 56 may be formed such that second lands 34, third lands 36, and fourth lands 37 are provided with openings corresponding to openings 57 of first lands 33.

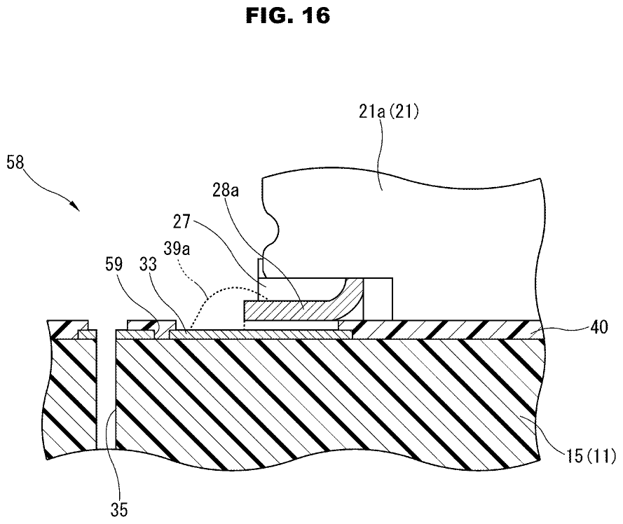

FIG. 16 is an illustrative view schematically showing a focused part of an electric actuator device 58 according to an eighth embodiment: in detail, a focused part of first rigid part 15 loaded with electrolytic capacitors 21.

Electric actuator device 58 according to the eighth embodiment is configured generally similarly to electric actuator device 1 according to the first embodiment, but is formed such that: each of first through holes 35 is positioned outside first land 33; the opening of the first end of each of first through holes 35 is not closed; and each of first through holes 35 is accompanied by an opening (i.e., a slit) 59 formed between first land 33 and an wiring pattern connected to the first end of first through hole 35.

Each of openings 59 is a rectangular through hole extending through the wiring pattern connected to the first end of first through hole 35, and is disposed between two points: the capacitor connection point in first land 33 connected to first electrode terminal 28a of first capacitor 21a, and the conduction passage connection point in the wiring pattern connected to first through hole 35. Each of openings 59 is positioned outside first capacitor 21a in the radial direction of first capacitor 21a, and is closed by a member such as first resist 40. Each of openings 59 includes an interior that does not contain the copper foil forming first land 33, wherein the interior is an insulated region.

Electric actuator device 58 according to the eighth embodiment presents effects substantially same with electric actuator device 1 according to the first embodiment.

Electric actuator device 58 may be formed such that second lands 34, third lands 36, and fourth lands 37 are provided with openings corresponding to openings 59 in first lands 33.

As shown in FIG. 15, each of openings 59 may be divided into two parts so as not to overlap with the shortest path between the capacitor connection point and the conduction passage connection point.

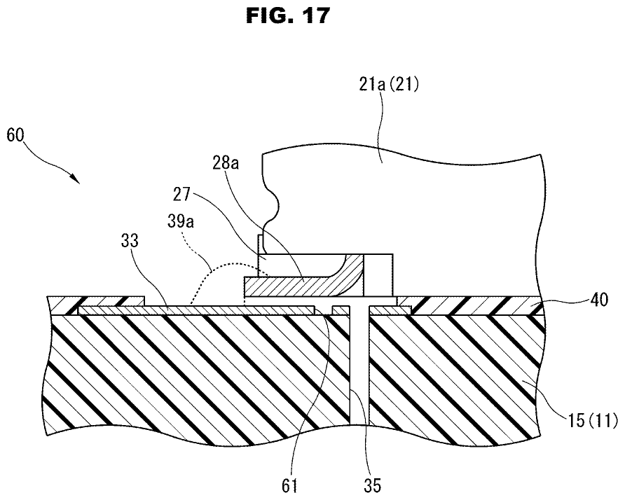

FIG. 17 is an illustrative view schematically showing a focused part of an electric actuator device 60 according to a ninth embodiment: in detail, a focused part of first rigid part 15 loaded with electrolytic capacitors 21.

Electric actuator device 60 according to the ninth embodiment is configured generally similarly to electric actuator device 1 according to the first embodiment, but is formed such that the first end of each of first through holes 35 faces the bottom surface of the body of first capacitor 21a. Thus, in electric actuator device 60 according to the ninth embodiment, each of first through holes 35 is positioned inside first capacitor 21a in the radial direction of first capacitor 21a, i.e., positioned to overlap with first capacitor 21a, when viewed from the direction perpendicular to first mounting surface 31 and second mounting surface 32 of circuit board 11. Furthermore, in electric actuator device 60 according to the ninth embodiment, the opening of the first end of each of first through holes 35 is not closed.

In addition to the above, in electric actuator device 60 according to the ninth embodiment, each of first lands 33 includes an opening (i.e., a slit) 61 extending through first land 33. Each of openings 61 faces the bottom surface of the body of first capacitor 21a, and is positioned outside with respect to first through hole 35 in the radial direction of first capacitor 21a. Each of openings 61 includes an interior that does not contain the copper foil forming first land 33, wherein the interior is an insulated region.

Although omitted in the drawing, in electric actuator device 60 according to the ninth embodiment, the second end of each of first through holes 35 faces the bottom surface of the body of second capacitor 21b. Thus, in electric actuator device 60 according to the ninth embodiment, each of first through holes 35 is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11. Furthermore, in electric actuator device 60 according to the ninth embodiment, the opening of the second end of each of first through holes 35 is not closed.

Electric actuator device 60 according to the ninth embodiment presents effects substantially same with electric actuator device 1 according to the first embodiment.

Electric actuator device 60 may be formed such that second lands 34 are provided with openings corresponding to openings 61 of first lands 33.

As shown in FIG. 15, each of openings 61 may be divided into two parts so as not to overlap with the shortest path between the capacitor connection point and the conduction passage connection point.

Electric actuator device 60 may be formed such that each of second through holes 38 is positioned inside first and second capacitors 21a and 21b in the radial direction of first and second capacitors 21a and 21b, i.e., positioned to overlap with first and second capacitors 21a and 21b, when viewed from the direction perpendicular to first and second mounting surfaces 31 and 32 of circuit board 11. In this case, third lands 36 and fourth lands 37 may include openings corresponding to openings 61 of first lands 33.

Each of the openings in third lands 36 and fourth lands 37 corresponding to openings 61 in first lands 33 may be divided into two parts so as not to overlap with the shortest path between the capacitor connection point and the conduction passage connection point, as shown in FIG. 15.

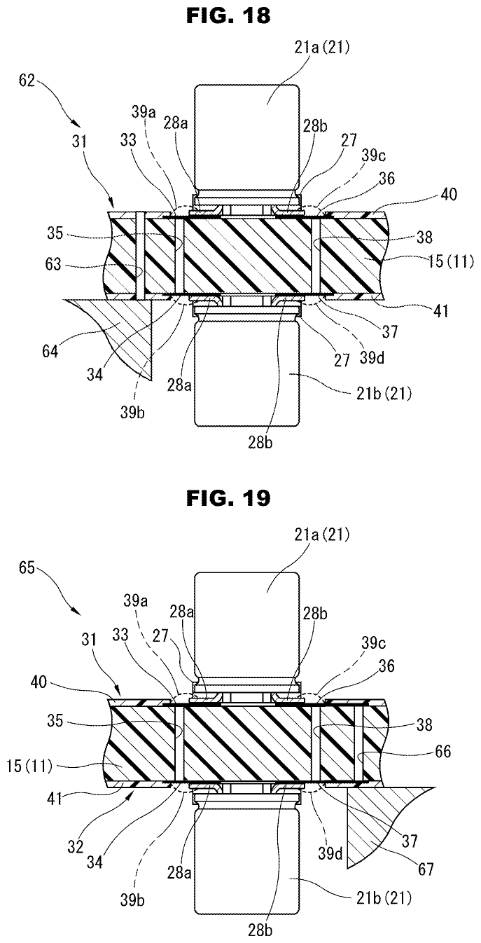

FIG. 18 is an illustrative view schematically showing a focused part of an electric actuator device 62 according to a tenth embodiment: in detail, a focused part of first rigid part 15 loaded with electrolytic capacitors 21.

Electric actuator device 62 according to the tenth embodiment is configured generally similarly to electric actuator device 1 according to the first embodiment, but is formed such that first rigid part 15 of circuit board 11 includes a through hole 63 electrically discontinuous with the power source line and electrically discontinuous with the wiring line of the cathode potential connected to third lands 36 and fourth lands 37. Each of through holes 63 extends through circuit board 11, and is positioned outside with respect to first through hole 35 in the radial direction of electrolytic capacitors 21, and is in thermal contact with a metallic member 64 disposed on second mounting surface 32 of first rigid part 15. The thermal contact is contact that allows movement of energy due to radiation.

Electric actuator device 62 according to the tenth embodiment presents effects substantially same with electric actuator device 1 according to the first embodiment, and furthermore serves to facilitate heat radiation from circuit board 11 with use of through hole 63 and metallic member 64.

FIG. 19 is an illustrative view schematically showing a focused part of an electric actuator device 65 according to an eleventh embodiment: in detail, a focused part of first rigid part 15 loaded with electrolytic capacitors 21.

Electric actuator device 65 according to the eleventh embodiment is configured generally similarly to electric actuator device 1 according to the first embodiment, but is formed such that first rigid part 15 of circuit board 11 includes a through hole 66 electrically continuous with the wiring line of the cathode potential connected to third lands 36 and fourth lands 37. Each of through holes 66 extends through circuit board 11, and is positioned outside with respect to second through holes 38 in the radial direction of electrolytic capacitors 21, and is in thermal contact with a metallic member 67 disposed on second mounting surface 32 of first rigid part 15. The thermal contact is contact that allows movement of energy due to radiation.

Electric actuator device 65 according to the eleventh embodiment presents effects substantially same with electric actuator device 1 according to the first embodiment, and furthermore serves to facilitate heat radiation from circuit board 11 with use of through hole 66 and metallic member 67.

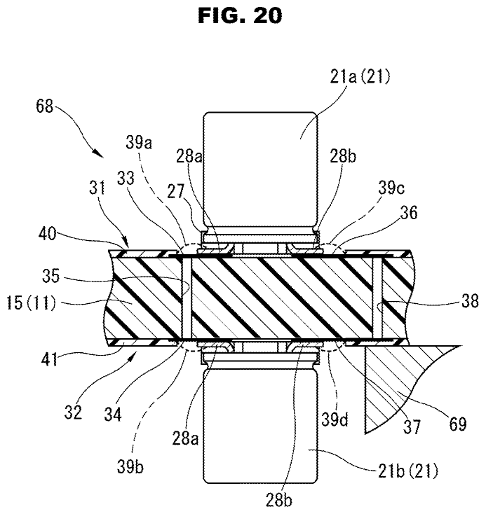

FIG. 20 is an illustrative view schematically showing a focused part of an electric actuator device 68 according to a twelfth embodiment: in detail, a focused part of first rigid part 15 loaded with electrolytic capacitors 21.

Electric actuator device 68 according to the twelfth embodiment is configured generally similarly to electric actuator device 1 according to the first embodiment, but is formed such that each of second through holes 38 is positioned outside third land 36 and fourth land 37.

Furthermore, each of second through holes 38 is in thermal contact with a metallic member 69 disposed on second mounting surface 32 of first rigid part 15. The thermal contact is contact that allows movement of energy due to radiation. Thus, in electric actuator device 68 according to the twelfth embodiment, each of second through holes 38 serves as a through hole structured to be in contact with metallic members 69 and thereby facilitate heat radiation from circuit board 11.

Electric actuator device 68 according to the twelfth embodiment presents effects substantially same with electric actuator device 1 according to the first embodiment, and furthermore serves to facilitate heat radiation from circuit board 11 with use of second through holes 38 and metallic member 69.

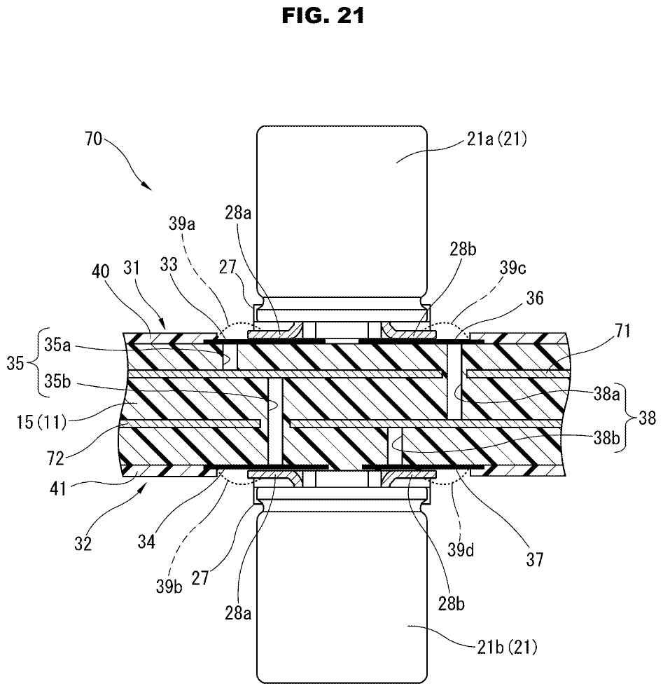

FIG. 21 is an illustrative view schematically showing a focused part of an electric actuator device 70 according to a thirteenth embodiment: in detail, a focused part of first rigid part 15 loaded with electrolytic capacitors 21.

Electric actuator device 70 according to the thirteenth embodiment is configured generally similarly to electric actuator device 1 according to the first embodiment, but is formed such that each of first through holes 35 and second through holes 38 is divided into two parts. The divided two parts of each of first through holes 35 are connected to each other via a first inner layer pattern 71. The divided two parts of each of second through holes 38 are connected to each other via a second inner layer pattern 72. First inner layer pattern 71 and second inner layer pattern 72 are electrically disconnected with each other.

Each of first through holes 35 includes a first capacitor side part 35a and a second capacitor side part 35b, wherein: first capacitor side part 35a includes a first end connected to first land 33 and a second end connected to first inner layer pattern 71; and second capacitor side part 35b includes a first end connected to first inner layer pattern 71 and a second end connected to second land 34.

In each of first through holes 35, first capacitor side part 35a is positioned outside first capacitor 21a and second capacitor 21b in the radial direction of first capacitor 21a and second capacitor 21b, when viewed from the direction perpendicular to first mounting surface 31 and second mounting surface 32 of circuit board 11.

In each of first through holes 35, second capacitor side part 35b is positioned inside first capacitor 21a and second capacitor 21b in the radial direction of first capacitor 21a and second capacitor 21b, i.e., positioned to overlap with first capacitor 21a and second capacitor 21b, when viewed from the direction perpendicular to first mounting surface 31 and second mounting surface 32 of circuit board 11.

Each of second through holes 38 includes a first capacitor side part 38a and a second capacitor side part 38b, wherein: first capacitor side part 38a includes a first end connected to third land 36 and a second end connected to second inner layer pattern 72; and second capacitor side part 38b includes a first end connected to second inner layer pattern 72 and a second end connected to fourth land 37.

In each of second through holes 38, first capacitor side part 38a is positioned outside first capacitor 21a and second capacitor 21b in the radial direction of first capacitor 21a and second capacitor 21b, when viewed from the direction perpendicular to first mounting surface 31 and second mounting surface 32 of circuit board 11.

In each of second through holes 38, second capacitor side part 38b is positioned inside first capacitor 21a and second capacitor 21b in the radial direction of first capacitor 21a and second capacitor 21b, i.e., positioned to overlap with first capacitor 21a and second capacitor 21b, when viewed from the direction perpendicular to first mounting surface 31 and second mounting surface 32 of circuit board 11.

Electric actuator device 70 according to the thirteenth embodiment presents effects substantially same with electric actuator device 1 according to the first embodiment.

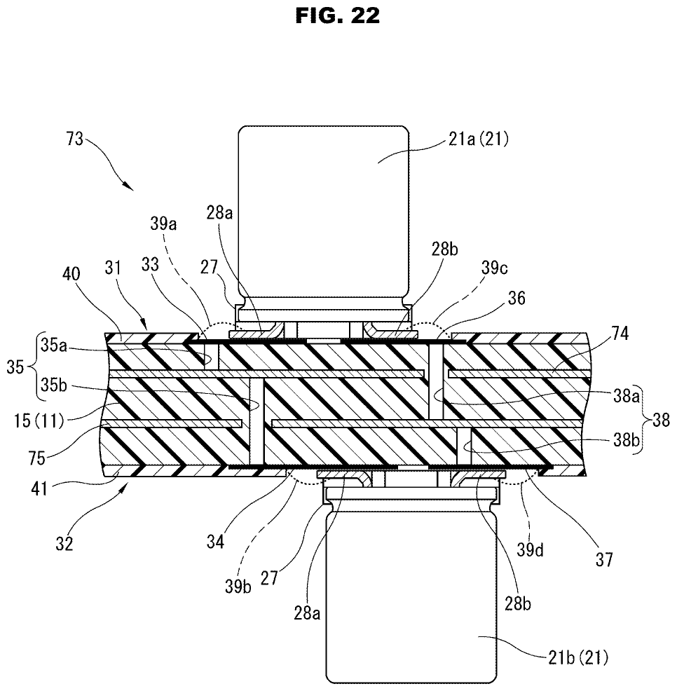

FIG. 22 is an illustrative view schematically showing a focused part of an electric actuator device 73 according to a fourteenth embodiment: in detail, a focused part of first rigid part 15 loaded with electrolytic capacitors 21.

Electric actuator device 73 according to the fourteenth embodiment is configured generally similarly to electric actuator device 51 according to the second embodiment, but is formed such that each of first through holes 35 and second through holes 38 is divided into two parts. The divided two parts of each of first through holes 35 are connected to each other via a first inner layer pattern 74. The divided two parts of each of second through holes 38 are connected to each other via a second inner layer pattern 75. First inner layer pattern 74 and second inner layer pattern 75 are electrically disconnected with each other.

Each of first through holes 35 includes first capacitor side part 35a and second capacitor side part 35b, wherein: first capacitor side part 35a includes the first end connected to first land 33 and the second end connected to first inner layer pattern 74; and second capacitor side part 35b includes the first end connected to first inner layer pattern 74 and the second end connected to second land 34.

In each of first through holes 35, first capacitor side part 35a is positioned outside first capacitor 21a and second capacitor 21b in the radial direction of first capacitor 21a and second capacitor 21b, when viewed from the direction perpendicular to first mounting surface 31 and second mounting surface 32 of circuit board 11.

In each of first through holes 35, second capacitor side part 35b is positioned inside first capacitor 21a in the radial direction of first capacitor 21a, i.e., positioned to overlap with first capacitor 21a, when viewed from the direction perpendicular to first mounting surface 31 and second mounting surface 32 of circuit board 11.

In each of first through holes 35, second capacitor side part 35b is positioned outside second capacitor 21b in the radial direction of second capacitor 21b, when viewed from the direction perpendicular to first mounting surface 31 and second mounting surface 32 of circuit board 11.

Each of second through holes 38 includes first capacitor side part 38a and second capacitor side part 38b, wherein: first capacitor side part 38a includes the first end connected to third land 36 and the second end connected to second inner layer pattern 75; and second capacitor side part 38b includes the first end connected to second inner layer pattern 75 and the second end connected to fourth land 37.

In each of second through holes 38, both of first capacitor side part 38a and second capacitor side part 38b are positioned outside first capacitor 21a in the radial direction of first capacitor 21a, and are positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11.

Electric actuator device 70 according to the thirteenth embodiment presents effects substantially same with electric actuator device 51 according to the second embodiment.

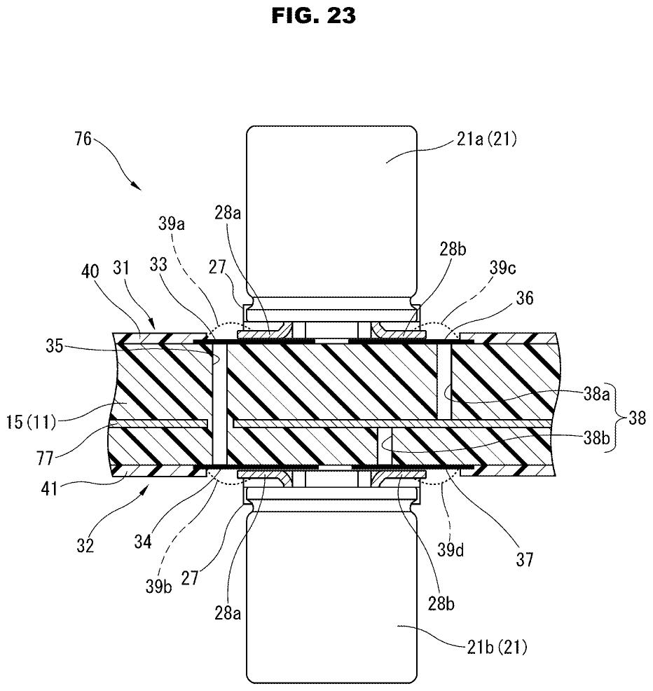

FIG. 23 is an illustrative view schematically showing a focused part of an electric actuator device 76 according to a fifteenth embodiment: in detail, a focused part of first rigid part 15 loaded with electrolytic capacitors 21.

Electric actuator device 76 according to the fifteenth embodiment is configured generally similarly to electric actuator device 1 according to the first embodiment, but is formed such that each of second through holes 38 is divided into two parts. The divided two parts of each of second through holes 38 are connected to each other via an inner layer pattern 77.

Each of second through holes 38 includes first capacitor side part 38a and second capacitor side part 38b, wherein: first capacitor side part 38a includes the first end connected to third land 36 and the second end connected to inner layer pattern 77; and second capacitor side part 38b includes the first end connected to inner layer pattern 77 and the second end connected to fourth land 37.

In each of second through holes 38, first capacitor side part 38a is positioned outside first capacitor 21a and second capacitor 21b in the radial direction of first capacitor 21a and second capacitor 21b, when viewed from the direction perpendicular to first mounting surface 31 and second mounting surface 32 of circuit board 11.

In each of second through holes 38, second capacitor side part 38b is positioned inside first capacitor 21a and second capacitor 21b in the radial direction of first capacitor 21a and second capacitor 21b, i.e., positioned to overlap with first capacitor 21a and second capacitor 21b, when viewed from the direction perpendicular to first mounting surface 31 and second mounting surface 32 of circuit board 11.

Inner layer pattern 77 is formed in an inner layer of circuit board 11, and is connected to the ground line. Thus, second through holes 38 are connected to a ground line (i.e., inner layer pattern 77) formed in the inner layer of circuit board 11.

Electric actuator device 76 according to the fifteenth embodiment presents effects substantially same with electric actuator device 1 according to the first embodiment.

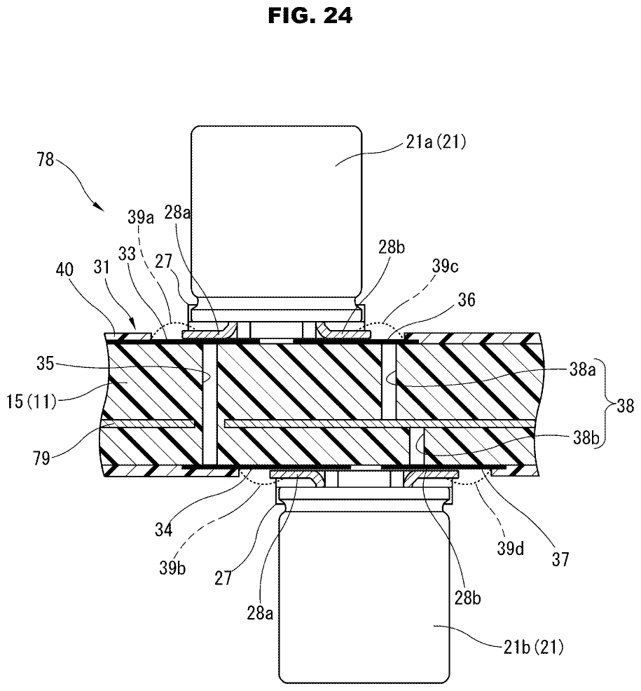

FIG. 24 is an illustrative view schematically showing a focused part of an electric actuator device 78 according to a sixteenth embodiment: in detail, a focused part of first rigid part 15 loaded with electrolytic capacitors 21.

Electric actuator device 78 according to the sixteenth embodiment is configured generally similarly to electric actuator device 51 according to the second embodiment, but is formed such that each of first through holes 35 is positioned inside first capacitor 21a in the radial direction of first capacitor 21a, while each of second through holes 38 is divided into two parts. The divided two parts of each of second through holes 38 are connected to each other via an inner layer pattern 79.

In detail, in electric actuator device 78 according to the sixteenth embodiment, each of first through holes 35 is positioned inside first capacitor 21a in the radial direction of first capacitor 21a, i.e., positioned to overlap with second capacitor 21a, and is positioned outside second capacitor 21b in the radial direction of second capacitor 21b, when viewed from the direction perpendicular to first mounting surface 31 and second mounting surface 32 of circuit board 11.

Each of second through holes 38 includes first capacitor side part 38a and second capacitor side part 38b, wherein: first capacitor side part 38a includes the first end connected to third land 36 and the second end connected to inner layer pattern 79; and second capacitor side part 38b includes the first end connected to inner layer pattern 79 and the second end connected to fourth land 37.

In each of second through holes 38, both of first capacitor side part 38a and second capacitor side part 38b are positioned outside first capacitor 21a in the radial direction of first capacitor 21a, when viewed from the direction perpendicular to first mounting surface 31 and second mounting surface 32 of circuit board 11.

In each of second through holes 38, second capacitor side part 38b is positioned inside second capacitor 21b in the radial direction of second capacitor 21b, i.e., positioned to overlap with second capacitor 21b, when viewed from the direction perpendicular to first mounting surface 31 and second mounting surface 32 of circuit board 11.

Inner layer pattern 79 is formed in an inner layer of circuit board 11, and is connected to the ground line. Thus, second through holes 38 are connected to the ground line (i.e., inner layer pattern 79) formed in the inner layer of circuit board 11.

Electric actuator device 78 according to the sixteenth embodiment presents effects substantially same with electric actuator device 51 according to the second embodiment.

The above describes the specific embodiments of the present invention. However, the present invention is not limited to the above embodiments, but may be variously modified within scope of technical ideas of the invention.

For example, the conduction passages may be not the through holes but vias instead.

The above embodiments may be modified to divide each of first through holes 35 into two parts by an inner layer pattern connected to the power source line. In other words, each of first through holes 35 may be connected to the inner layer pattern (i.e., the power source line) formed in an inner layer of circuit board 11. In this case, first lands 33 may be electrically discontinuous with the power source line on first mounting surface 31.

1. An electronic control device comprising:
a circuit board including first and second surfaces structured to be loaded with electronic components;
a first capacitor mounted to the first surface of the circuit board; and
a second capacitor mounted to the second surface of the circuit board and disposed oppositely to the first capacitor at least partially,
wherein the circuit board further includes:
a first land disposed in the first surface of the circuit board and connected to the first capacitor;
a second land disposed in the second surface of the circuit board and connected to the second capacitor; and
a conduction passage establishing electrical continuity from the first land and the second land to a same power source line via the circuit board.

2. The electronic control device as claimed in claim 1, wherein:
the first capacitor includes a terminal connected to the first land and positioned apart from the conduction passage by a distance smaller than a diameter of the first capacitor; and
the second capacitor includes a terminal connected to the second land and positioned apart from the conduction passage by a distance smaller than a diameter of the second capacitor.

3. The electronic control device as claimed in claim 1, wherein the conduction passage is positioned in the first land or the second land.

4. The electronic control device as claimed in claim 1, wherein the conduction passage is connected to the power source line formed in an inner layer of the circuit board.

5. The electronic control device as claimed in claim 1, wherein:
the power source line is formed in the first surface of the circuit board; and
the second capacitor is connected to the power source line via the first land.

6. The electronic control device as claimed in claim 1, wherein:
the circuit board includes a through hole that is electrically discontinuous with a wiring with an anode potential of the circuit board;
the power source line is formed in the first surface of the circuit board; and
the through hole is in thermal contact with a metallic member disposed on the second surface of the circuit board.

7. The electronic control device as claimed in claim 2, wherein:
the first land overlaps with the first capacitor; and
the conduction passage faces the first capacitor.

8. The electronic control device as claimed in claim 3, wherein:
the first land includes an opening extending through the first land; and
the opening is positioned between a capacitor connection point of the first land connected to the first capacitor and a conduction passage connection point of the first land connected to the conduction passage.

9. The electronic control device as claimed in claim 3, wherein the conduction passage is positioned in the first land and the second land.

10. The electronic control device as claimed in claim 5, the electronic control device further comprising:
a filter circuit component mounted to the first surface of the circuit board,
wherein the second capacitor is connected to the filter circuit component via the conduction passage.
